(19) United States
(12) Patent Application Publication
(10) Pub. No.: US 2024/0203879 A1
(43) Pub. Date: Jun. 20, 2024

(54) LOW-RESISTANCE VIA TO BACKSIDE POWER RAIL

(71) Applicant: INTERNATIONAL BUSINESS MACHINES CORPORATION, Armonk, NY (US)

(72) Inventors: Ruilong Xie, Niskayuna, NY (US); Julien Frougier, Albany, NY (US); Chanro Park, Clifton Park, NY (US); Min Gyu Sung, Latham, NY (US); Juntao Li, Cohoes, NY (US)

(21) Appl. No.: 18/067,127

(22) Filed: Dec. 16, 2022

(51) Int. Cl. H01L 23/528; H01L 21/768; H01L 21/8234; H01L 23/522; H01L 23/532; H01L 27/088

(52) U.S. Cl. CPC H01L 23/5286; H01L 21/76897; H01L 21/823475; H01L 23/5226; H01L 23/5228; H01L 23/5283; H01L 23/53266; H01L 23/53295; H01L 27/088; H01L 29/78696

(57) ABSTRACT

Semiconductor devices and methods of forming the same include a front-end-of-line (FEOL) layer including a FEOL device. A backside power line is on a back side of the FEOL layer. A conductive structure contacts the FEOL device at a front side of the FEOL layer and extends through the FEOL layer to contact the backside power line. The conductive structure includes a frontside part that includes a metal liner and a first fill material and a backside part that includes a second fill material having an outer surface that aligns with an outer surface of the metal liner.

### BACKGROUND

The present invention generally relates to semiconductor device fabrication and, more particularly, to formation of vias in devices with backside power rails.

A semiconductor device, such as an integrated chip with transistors, may be formed with power and signal lines on both sides of the device. This can increase the available options for routing the lines, leading to improvements in areal device density, but may also increase the complexity of forming connections between the active devices on the chip and the backside power lines. For example, vias may be formed from the front side of the chip to the back side of the chip to make electrical connections between frontside contacts and backside power lines, and the resistance of these vias may diminish the performance of the device.

### SUMMARY

A semiconductor device includes a front-end-of-line (FEOL) layer including a FEOL device. A backside power line is on a back side of the FEOL layer. A conductive structure contacts the FEOL device at a front side of the FEOL layer and extends through the FEOL layer to contact the backside power line. The conductive structure includes a frontside part that includes a metal liner and a first fill material and a backside part that includes a second fill material having an outer surface that aligns with an outer surface of the metal liner.

A semiconductor device includes FEOL layer including a FEOL device. A back-end-of-line (BEOL) layer is on a front side of the FOEL layer. A backside power line is on a back side of the FEOL layer. A conductive structure contacts the FEOL device at the front side of the FEOL layer and that extends through the FEOL layer to contact the backside power line. The conductive structure includes a frontside part that includes a metal liner and a backside part that does not include the metal liner. A dielectric liner is on sidewalls of the backside part of the conductive structure and includes including a first dielectric material. An interlayer dielectric is around the dielectric liner and includes a second dielectric material different from the first dielectric material.

A method for forming a semiconductor device includes forming a FEOL layer that includes a FEOL device. A frontside conductive contact is formed on the FEOL device to include a metal liner between the frontside conductive contact and the FEOL device. A backside conductive contact is formed in electrical contact with the frontside conductive contact, an outer surface of the backside conductive contact aligning with an outer surface of the metal liner.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a top-down view of a step in the fabrication of a semiconductor device that includes a low-resistance via to a backside power rail, showing cross-sections AA, BB, and CC, in accordance with an embodiment of the present invention;

FIG. 2 is a set of cross-sectional views of a step in the fabrication of a semiconductor device that includes a low-resistance via to a backside power rail, showing the formation of front-end-of-line (FEOL) devices with a dielectric structure that extends to an underlying substrate, in accordance with an embodiment of the present invention;

FIG. 3 is a set of cross-sectional views of a step in the fabrication of a semiconductor device that includes a low-resistance via to a backside power rail, showing removal of part of the dielectric structure to open a via to the underlying substrate, in accordance with an embodiment of the present invention;

FIG. 4 is a set of cross-sectional views of a step in the fabrication of a semiconductor device that includes a low-resistance via to a backside power rail, showing the removal of a sacrificial plug in the via, in accordance with an embodiment of the present invention;

FIG. 5 is a set of cross-sectional views of a step in the fabrication of a semiconductor device that includes a low-resistance via to a backside power rail, showing the removal of dielectric material to expose topside surfaces of the FEOL devices, in accordance with an embodiment of the present invention;

FIG. 6 is a set of cross-sectional views of a step in the fabrication of a semiconductor device that includes a low-resistance via to a backside power rail, showing the formation of a top part of a conductive via that includes a metal liner, in accordance with an embodiment of the present invention;

FIG. 7 is a set of cross-sectional views of a step in the fabrication of a semiconductor device that includes a low-resistance via to a backside power rail, showing the formation of back-end-of-line (BEOL) layers on a front side of the FEOL layer, in accordance with an embodiment of the present invention;

FIG. 8 is a set of cross-sectional views of a step in the fabrication of a semiconductor device that includes a low-resistance via to a backside power rail, showing removal of the substrate from the back side of the FEOL layer, in accordance with an embodiment of the present invention;

FIG. 9 is a set of cross-sectional views of a step in the fabrication of a semiconductor device that includes a low-resistance via to a backside power rail, showing the formation of a backside interlayer dielectric that leaves the sacrificial plug exposed, in accordance with an embodiment of the present invention;

FIG. 10 is a set of cross-sectional views of a step in the fabrication of a semiconductor device that includes a low-resistance via to a backside power rail, showing removal the sacrificial plug, in accordance with an embodiment of the present invention;

FIG. 11 is a set of cross-sectional views of a step in the fabrication of a semiconductor device that includes a low-resistance via to a backside power rail, showing removal of an exposed part of the metal liner in the via, in accordance with an embodiment of the present invention;

FIG. 12 is a set of cross-sectional views of a step in the fabrication of a semiconductor device that includes a low-resistance via to a backside power rail, showing selective deposition of conductive material to form a bottom part of the conductive via, in accordance with an embodiment of the present invention;

FIG. 13 is a set of cross-sectional views of a step in the fabrication of a semiconductor device that includes a low-resistance via to a backside power rail, the formation of a backside power rail in electrical contact with the conductive via, in accordance with an embodiment of the present invention; and

FIG. 14 is a block/flow diagram of a method of fabricating a semiconductor device that includes a low-resistance via to a backside power rail, in accordance with an embodiment of the present invention.

### DETAILED DESCRIPTION

Semiconductor devices may be formed with vias to backside power rails, but the resistance of the vias may be limited by their width. To maximize the areal density of devices on the wafer, the width of the vias may be minimized, but this results in a corresponding increase in via resistance. To help mitigate the increase in resistance, the via may be formed in two stages. A first stage may be formed from the front side of the device, with a metal liner being formed to promote adhesion of the conductive material of the via and/or to prevent diffusion of the conductive material of the via into surrounding dielectric structures. The second stage may be formed from the back side of the device, with no metal liner being needed. The absence of the metal liner in this second stage increases the effective width of the via and thus decreases the resistance of the structure, as compared to a via that includes a metal liner along its entire length. The first stage, meanwhile, has a relatively large width and so its resistance is not significantly constrained by the presence of the liner. As used herein, the term “low-resistance” refers to a conductive via structure that has a resistance lower than would be provided by a structure with a similar shape and formed with similar materials that has a full metal lining.

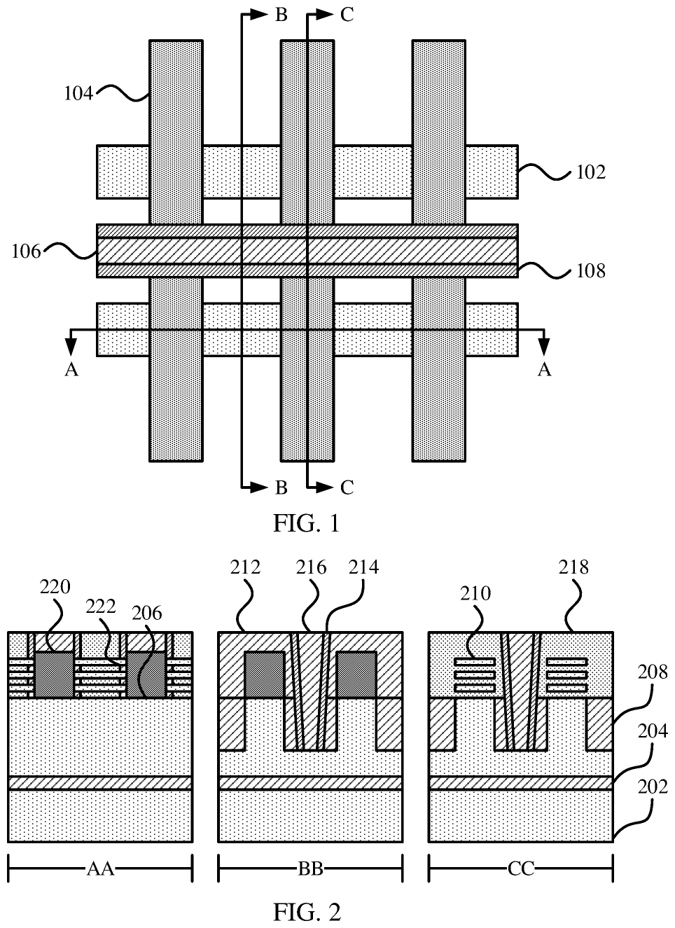

Referring now to FIG. 1, a top-down view of a step in the fabrication of a semiconductor device is shown. A set of semiconductor channel structures 102 are shown, with gates 104 across them. A gate cut structure includes a dielectric liner 108 and a dielectric fill 106 which may be formed from different dielectric materials. The gate cut structure separates the gates 104 into different device regions. In some examples, the gate cut structure may not separate all gates in this fashion, resulting in devices that are tied together by a shared gate.

Three cross-sectional planes are indicated. A first cross-sectional plane, AA, cuts through and parallel to a long dimension of a semiconductor channel structure 102. A second cross-sectional plane, BB, cuts perpendicular to the semiconductor channel structures 102 in a region outside of the gates 104. A third cross-sectional plane, CC, cuts perpendicular to the semiconductor channel structures 102 and through a gate 104.

Referring now to FIG. 2, a set of cross-sectional views are shown, including views AA, BB, and CC, of a step in the fabrication of a semiconductor device. This step shows a stage of fabrication after the formation of front-end-of-line (FEOL) devices. The FEOL devices are formed on a device semiconductor substrate 206, which in turn is positioned on and separated from a bulk semiconductor substrate 202 by an etch stop layer 204. Shallow trench isolation (STI) regions 208 separate adjacent device regions from one another and may be filled with any appropriate dielectric material.

The device semiconductor substrate 206 may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. The bulk semiconductor substrate 202 may be formed from the same semiconductor material as the device semiconductor substrate 206 or may be formed from another semiconductor material. In some embodiments, the bulk semiconductor substrate 202 may instead be a non-semiconductor material. An etch stop layer 204 separates the bulk semiconductor substrate 202 from the device semiconductor substrate 206 and may be formed from any appropriate material, such as silicon germanium or silicon dioxide.

The FEOL devices may include active devices like transistors, for example including the nanosheet field effect transistors (FETs) depicted herein. It should be understood that any device may be used instead. Alternative forms of transistors include, but are not limited to, nanowire FETs, fin FETs, planar FETs, binary junction transistors, and vertical transfer FETs. Other types of device may be used in place of a transistor, including any appropriate passive or active device, such as capacitors, inductors, diodes, transmission lines, resistors, etc.

Following the example of FEOL devices that use nanosheet FETs, the devices may include nanosheet semiconductor channels 210, positioned in a device region between STI regions 208, gate stacks 218, and source/drain structures 220. The gate stacks 218 may include, for example, a gate dielectric layer (not shown), a work function metal layer (not shown), and a gate conductor. Source/drain structures 220 may be formed at ends of the nanosheet semiconductor channels 210. Inner dielectric spacers 222 may separate the gate stack 218 of a given nanosheet FET from the source/drain structures 220.

The nanosheet semiconductor channels 210 may be formed from any appropriate semiconductor material, such as a silicon-containing material. The source/drain structures 220 may be formed by epitaxial growth from sidewalls of the nanosheet semiconductor channels 210. The terms “epitaxial growth” and/or “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The gate dielectric layer may include a high-k dielectric material. Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum.

The work function metal layer may include a p-type work function metal layer or an n-type work function metal layer. As used herein, a “p-type work function metal layer” is a metal layer that effectuates a p-type threshold voltage shift. In one embodiment, the work function of the p-type work function metal layer ranges from 4.9 eV to 5.2 eV. As used herein, “threshold voltage” is the lowest attainable gate voltage that will turn on a semiconductor device, e.g., transistor, by making the channel of the device conductive. The term “p-type threshold voltage shift” as used herein means a shift in the Fermi energy of a p-type semiconductor device towards a valence band of silicon in the silicon containing substrate of the p-type semiconductor device. A “valence band” is the highest range of electron energies where electrons are normally present at absolute zero. In one embodiment, a p-type work function metal layer may be formed from titanium nitride, titanium aluminum nitride, ruthenium, platinum, molybdenum, cobalt, and alloys and combinations thereof.

As used herein, an “n-type work function metal layer” is a metal layer that effectuates an n-type threshold voltage shift. “N-type threshold voltage shift” as used herein means a shift in the Fermi energy of an n-type semiconductor device towards a conduction band of silicon in a silicon-containing substrate of the n-type semiconductor device. The “conduction band” is the lowest lying electron energy band of the doped material that is not completely filled with electrons. In one embodiment, the work function of the n-type work function metal layer ranges from 4.1 eV to 4.3 eV. In one embodiment, the n-type work function metal layer is formed from at least one of titanium aluminum, tantalum nitride, titanium nitride, hafnium nitride, hafnium silicon, or combinations thereof. It should be understood that titanium nitride may play the role of an n-type work function metal or a p-type work function metal, depending on the conditions of its deposition.

The gate conductor of gate stack 218 may be formed from any appropriate conductive metal such as, e.g., tungsten, nickel, titanium, molybdenum, tantalum, copper, platinum, silver, gold, ruthenium, iridium, rhenium, rhodium, cobalt, and alloys thereof. The gate conductor of gate stack 218 may alternatively be formed from a doped semiconductor material such as, e.g., doped polysilicon.

A gate cut structure separates the gate stack 218 into different device regions and includes a dielectric liner 214 and a dielectric fill. The gate cut structure may extend down to the bottom of an STI region 208, making contact with the device semiconductor substrate 206. The dielectric liner 214 may be formed from a first dielectric material, such as silicon nitride, and the dielectric fill 216 may be formed from a second dielectric material, such as silicon dioxide. An interlayer dielectric 212 may be formed over the device regions and around the gate cut structure and may include, e.g., silicon dioxide.

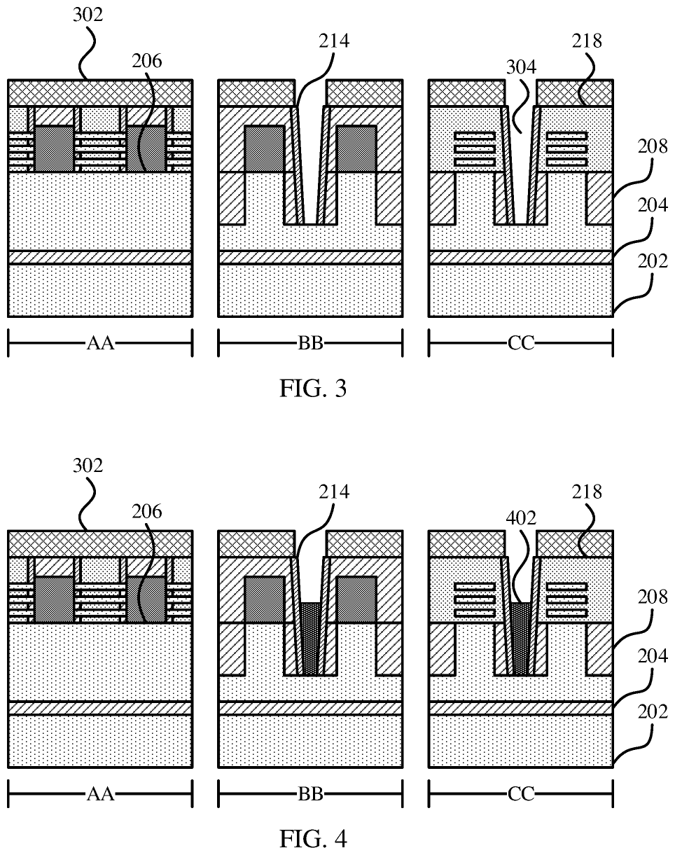

Referring now to FIG. 3, a set of cross-sectional views are shown, including views AA, BB, and CC, of a step in the fabrication of a semiconductor device. An organic planarizing layer is deposited over the top surface of the devices and may be patterned using, e.g., a photolithographic process. A selective anisotropic etch may then be used to remove the dielectric fill 216 from an exposed region, leaving the dielectric liner 214 intact and exposing a part of the device semiconductor substrate 206. A gap 304 is formed where the dielectric fill 216 was removed.

During the photolithographic process, a pattern is produced by applying a photoresist material to the surface to be etched, exposing the photoresist to a pattern of radiation, and then developing the pattern into the photoresist utilizing a resist developer. The resulting mask 302 defines regions of the underlying surface that are protected and regions that are exposed to the selective etch.

Reactive ion etching (RIE) is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation. As used herein, the term “selective” in reference to a material removal process denotes that the rate of material removal for a first material is greater than the rate of removal for at least another material of the structure to which the material removal process is being applied.

Referring now to FIG. 4, a set of cross-sectional views are shown, including views AA, BB, and CC, of a step in the fabrication of a semiconductor device. A sacrificial plug 402 is formed in the gap 304 by any appropriate deposition process. The sacrificial plug 402 may be formed from any material that has appropriate etch selectivity with respect to the other materials on the chip, such as a titanium oxide or silicon carbide. The sacrificial plug 402 may be formed by filling the gap 304 and then etching back to an appropriate height using any appropriately selective isotropic or anisotropic etch.

Exemplary deposition processes that may be used to form the sacrificial plug 402 may include chemical vapor deposition (CVD), physical vapor deposition (PVD), atomic layer deposition (ALD), or gas cluster ion beam (GCIB) deposition. CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface. In alternative embodiments that use GCIB deposition, a high-pressure gas is allowed to expand in a vacuum, subsequently condensing into clusters. The clusters can be ionized and directed onto a surface, providing a highly anisotropic deposition.

Referring now to FIG. 5, a set of cross-sectional views are shown, including views AA, BB, and CC, of a step in the fabrication of a semiconductor device. The interlayer dielectric 212 is patterned to create openings 502 that expose the top surfaces of the source/drain structures 220, for example using any appropriate photolithographic patterning process.

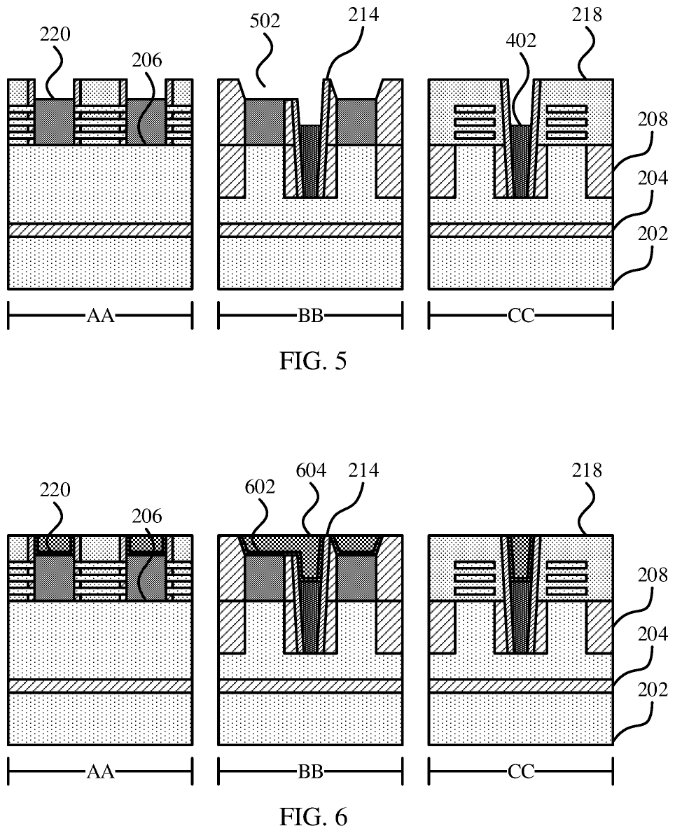

Referring now to FIG. 6, a set of cross-sectional views are shown, including views AA, BB, and CC, of a step in the fabrication of a semiconductor device. Source/drain contacts are formed in the openings 502, including a metal liner 602 and a contact conductor 604. The metal liner 602 may be formed using any appropriate conformal deposition process, and may include a material that will provide good adhesion to the material of the source/drain structures 220, for example a combination of a silicide liner, such as nickel, titanium, or nickel-platinum (which may not be conformal with greater thicknesses at horizontal surfaces) and a conformal metal liner, such as titanium nitride layer. The material of the metal liner 602 may also metallize the material of the source/drain structures 220, for example forming a titanium silicide that provides a good conductive interface between the metal liner 602 and the source/drain structures 220. The contact conductor 604 may be formed using any appropriate deposition process and may include any appropriate conductor, such as tungsten, cobalt, ruthenium, etc.

Any excess material from the metal liner 602 or the contact conductor 604 may be removed using a chemical mechanical planarization (CMP) process. CMP is performed using, e.g., a chemical or granular slurry and mechanical force to gradually remove upper layers of the device. The slurry may be formulated to be unable to dissolve, for example, the interlayer dielectric 212, resulting in the CMP process's inability to proceed any farther than that layer.

Referring now to FIG. 7, a set of cross-sectional views are shown, including views AA, BB, and CC, of a step in the fabrication of a semiconductor device. After formation of contacts to the devices in the FEOL layer 702, a first back-end-of-line (BEOL) layer 704 may be formed on the FEOL layer 702. The first BEOL layer 704 may include conductive vias and conductive lines that make electrical contact with structures of the FEOL devices. Additional BEOL layers 706 may be formed on the first BEOL layer 704, including any appropriate conductive vias and lines to form power and signal distribution networks to serve the devices of the FEOL layer 702.

A carrier wafer 708 may be bonded to the additional BEOL layers 706. The carrier wafer 708 may be formed from any material having appropriate mechanical properties, so as to provide stiffness and support to the wafer. The carrier wafer 708 may be used to maneuver the wafer, including turning the wafer over so that the backside of the wafer may be processed. Subsequent steps will therefore be described as processing the wafer from the side of the bulk semiconductor layer 202.

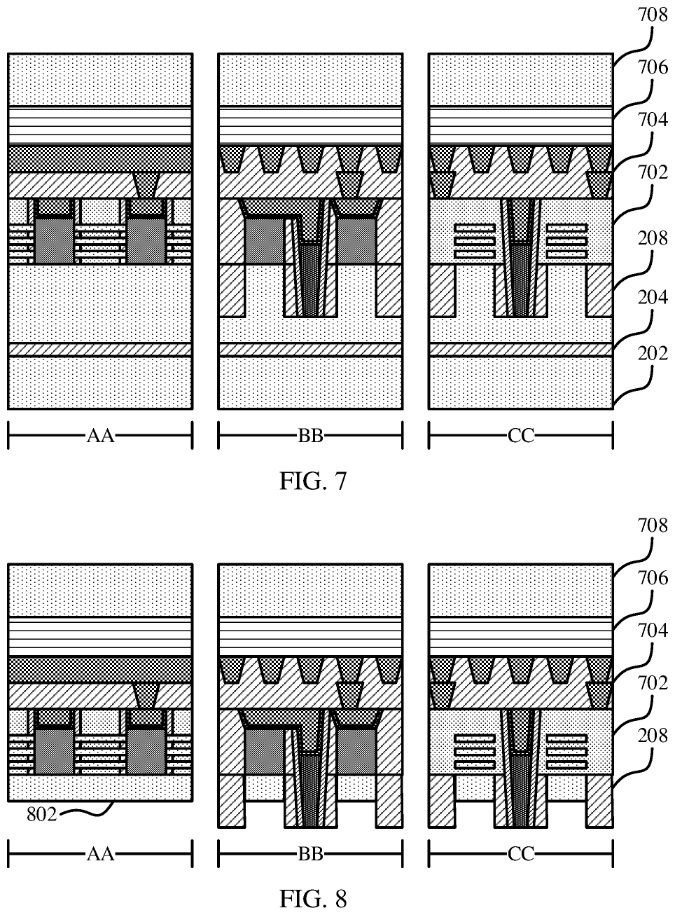

Referring now to FIG. 8, a set of cross-sectional views are shown, including views AA, BB, and CC, of a step in the fabrication of a semiconductor device. The bulk semiconductor layer 202 is removed using any appropriately selective etching process that stops on the etch stop layer 204. The etch stop layer 204 may then be removed by any appropriate etch or polishing process to expose the back side of the device semiconductor substrate 206. Part of the device semiconductor substrate 206 may then be removed, for example by a timed etch that exposes a surface of the sacrificial plug 402. The etch of the device semiconductor substrate 206 may leave semiconductor remnants 802 below the FEOL layer 702.

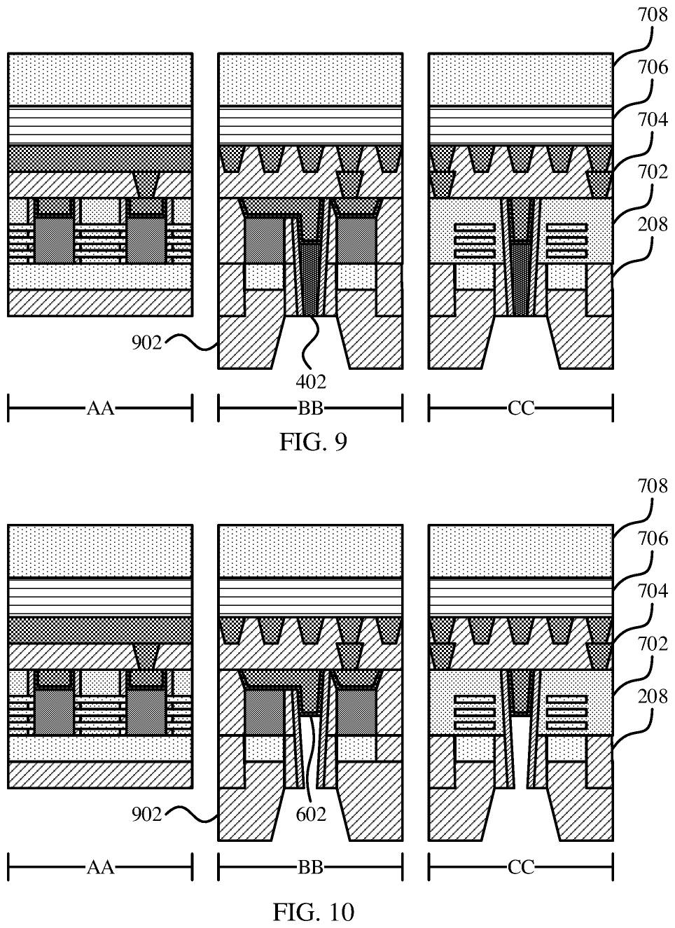

Referring now to FIG. 9, a set of cross-sectional views are shown, including views AA, BB, and CC, of a step in the fabrication of a semiconductor device. A bottom interlayer dielectric 902 is deposited on the back side of the wafer using any appropriate deposition process, for example depositing a layer of silicon dioxide. The interlayer dielectric 902 may be patterned using any appropriate photolithographic process to form an opening that exposes the bottom of the sacrificial plug 402.

Referring now to FIG. 10, a set of cross-sectional views are shown, including views AA, BB, and CC, of a step in the fabrication of a semiconductor device. The sacrificial plug 402 is selectively etched away using any appropriately selective etch, such as a wet or dry isotropic chemical etch. The resulting opening exposes the underside of the source/drain contact, in particular exposing part of the metal liner 602.

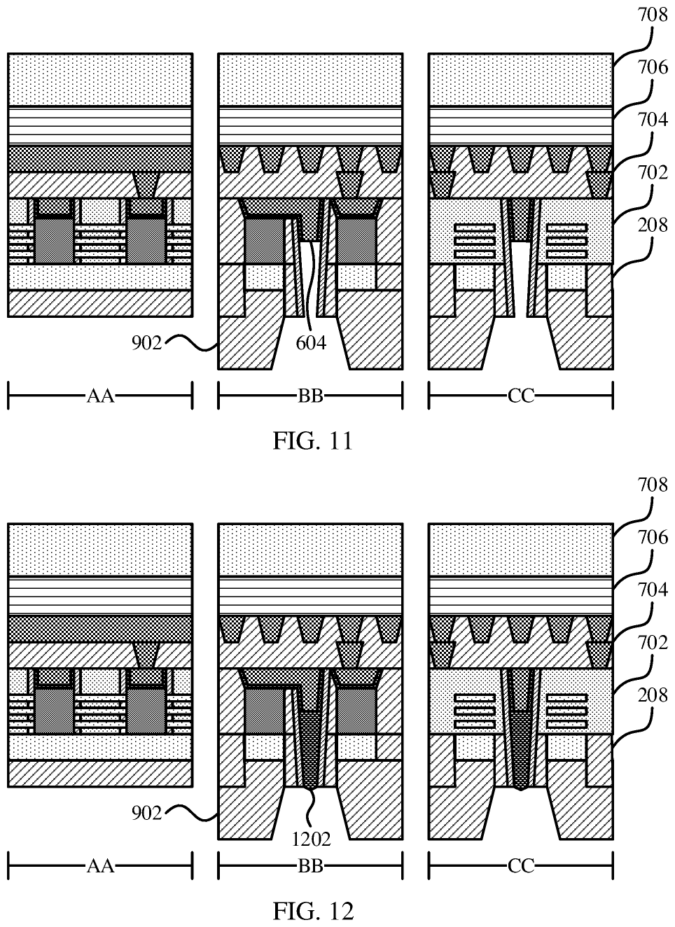

Referring now to FIG. 11, a set of cross-sectional views are shown, including views AA, BB, and CC, of a step in the fabrication of a semiconductor device. The exposed portion of the metal liner 602 is etched away using any appropriately selective etch, such as a wet or dry chemical etch. The bottom surface of the contact conductor 604 is then exposed.

Referring now to FIG. 12, a set of cross-sectional views are shown, including views AA, BB, and CC, of a step in the fabrication of a semiconductor device. Additional conductive material is selectively deposited on the exposed surface of the contact conductor 604, filling the via. The resulting conductive via 1202 has a top portion that is lined by metal liner 602 and a bottom portion that lacks the metal liner 602, coming into contact with the dielectric liner 214. In some cases, the selective deposition process may over-fill the via, such that additional conductive material extends beyond the farthest extend of the dielectric liner 214. The additional conductive material may be the same material as in the top portion, or may be a different conductive material. The selective deposition may over-fill the via, such that the conductive via 1202 extends past the lowermost extent of the dielectric liner 214.

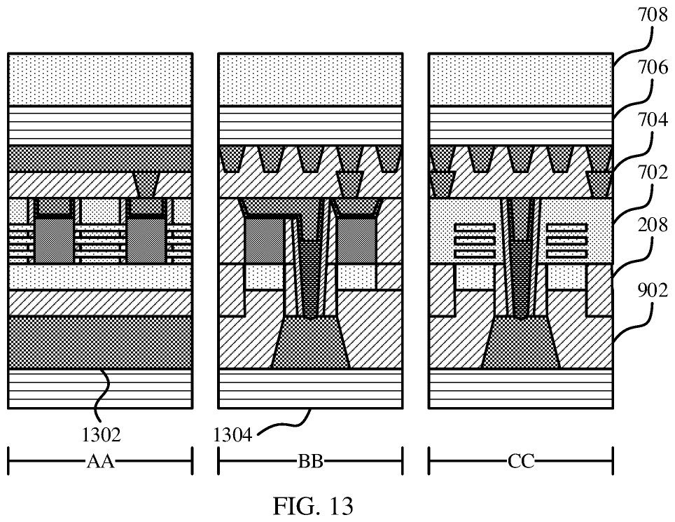

Referring now to FIG. 13, a set of cross-sectional views are shown, including views AA, BB, and CC, of a step in the fabrication of a semiconductor device. A backside power rail 1302 is formed by depositing a conductive material in the gap of the backside interlayer dielectric 902 using any appropriate deposition process. Any excess conductive material may be removed using, e.g., a CMP process that stops on the backside interlayer dielectric 902. The backside power rail may be formed from the same material as the bottom part of the conductive via 1202 or may be a different material. For example, the bottom part of the conductive via 1202 may be formed from cobalt or tungsten, and the backside power rail 1302 may be formed from copper.

A backside power distribution network 1304 or other backside BEOL layers may be formed on the backside interlayer dielectric 902 and may make electrical contact with the backside power rail 1302. For example, one or more layers of dielectric may be deposited and patterned to form trenches and vias, which may then be filled with conductive material to form the backside power distribution network 1304.

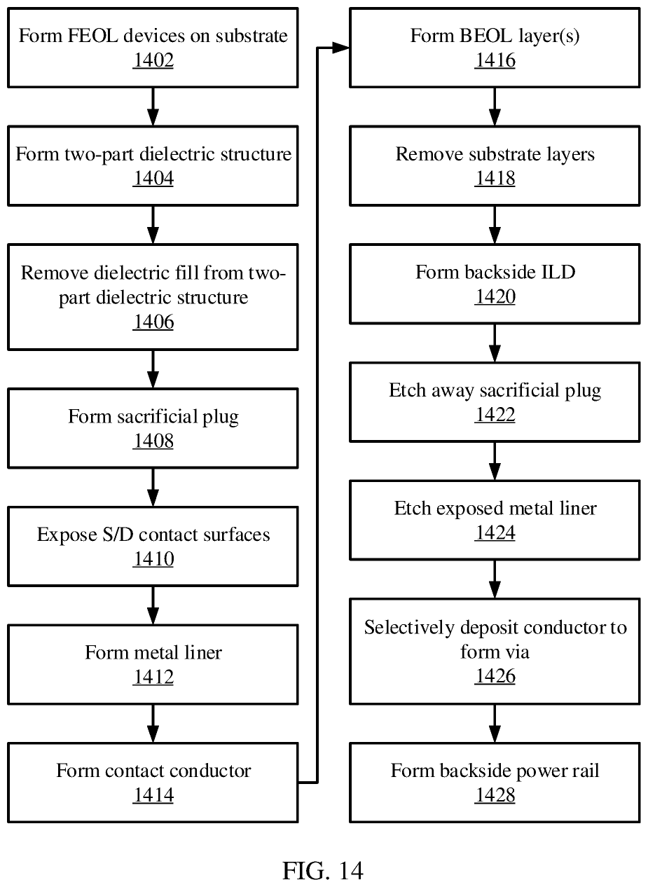

Referring now to FIG. 14, a method for fabricating a semiconductor device is shown. Block 1402 forms one or more FEOL devices on a device semiconductor substrate 206. As noted above, the device semiconductor substrate may be a silicon-containing material that is formed on an etch stop layer 204 and a bulk semiconductor substrate 202. Forming the FEOL device(s) may include growing a set of semiconductor layers, including channel layers and sacrificial layers, processing those layers to define channel regions 210, forming source/drain structures 220 on the channel regions 210, and forming a gate stack 218 on and around the channel regions 210.

Block 1404 forms a two-part dielectric structure at a side of a FEOL device. The two-part dielectric structure may be formed by, e.g., etching a via through an interlayer dielectric 212 and an STI structure 208 to expose the device semiconductor substrate 206. A dielectric liner 214 may be formed by conformally depositing a first dielectric material, such as silicon nitride, followed by any appropriate deposition of a second dielectric material, such as silicon dioxide, to form a dielectric fill 216.

Block 1406 removes the dielectric fill 216 from the two-part dielectric structure using a photolithographic mask 302 and any appropriately selective etch, leaving gap 304. Block 1408 then forms a sacrificial plug 402 within the gap 304, for example by depositing a material with appropriate etch selectivity and recessing the material to an appropriate height. For example, top surface of the sacrificial plug 402 may have a height that is between the top surface of an uppermost channel layer 210 and a top surface of the device semiconductor substrate 206.

Block 1412 conformally deposits metal liner 602 on the top surface of the source/drain structures 220 and block 1414 deposits contact conductor 604 over the metal liner 602. The metal liner may include, e.g., titanium nitride to provide adhesion to the conductive material of the contact conductor 604.

Block 1416 forms BEOL layers 704/706 on the front side of the FEOL layer 702, which may include any appropriate conductive lines and vias. Contact may be made between the first BEOL layer 704 and contacts of the FEOL device, for example to the source/drain structures 220 and the gate stack 218.

Block 1418 removes substrate layers, for example by removing the bulk semiconductor substrate 202, the etch stop layer 204, and by recessing the device semiconductor substrate 206 to form remnants 802. Block 1420 then forms backside interlayer dielectric 902, depositing a dielectric material, such as silicon dioxide, and patterning the dielectric material to expose the underside of the sacrificial plug 402.

Block 1422 etches away the sacrificial plug 402 using any appropriately selective etch, thereby exposing a bottom surface of the metal liner 602. Block 1424 then selectively etches away the exposed surface of the metal liner 602 to expose the bottom surface of the contact conductor 604. Block 1426 selectively deposits conductive material in the space left behind by the removal of the sacrificial plug 402, forming a lower part of the conductive via 1202 that does not include metal liner 602. The selective deposition may overfill the via, such that the conductive via extends past the lowermost extent of the dielectric liner 214. The selective deposition may deposit a same conductive material as the contact conductor 604, or may include a different conductive material. Block 1428 then forms a backside power rail 1302 that makes electrical contact with the via 1202. The backside power rail 1302 may include a same conductive material as the lower part of the conductive via 1202 or may include a different conductive material.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or backside interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing, particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one elements or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of a low-resistance backside power rail via (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a front-end-of-line (FEOL) layer including a FEOL device;
a backside power line on a back side of the FEOL layer; and
a conductive structure that contacts the FEOL device at a front side of the FEOL layer and that extends through the FEOL layer to contact the backside power line, including a frontside part that includes a metal liner and a first fill material and a backside part that includes a second fill material having an outer surface that aligns with an outer surface of the metal liner.

2. The semiconductor device of claim 1, wherein the frontside part of the conductive structure includes a first metal and the metal liner includes a metal nitride.

3. The semiconductor device of claim 2, wherein the metal liner further includes a metal silicide in direct contact with a source/drain structure of the FEOL device.

4. The semiconductor device of claim 2, wherein the backside part of the conductive structure includes a second metal, different from the first metal.

5. The semiconductor device of claim 4, wherein the backside power line includes a third metal, different from the second metal.

6. The semiconductor device of claim 1, further comprising a dielectric liner on sidewalls of the backside part of the conductive structure, formed from a first dielectric material.

7. The semiconductor device of claim 6, further comprising an interlayer dielectric around the dielectric liner, formed from a second dielectric material different from the first dielectric material.

8. The semiconductor device of claim 6, wherein the backside part of the conductive structure extends farther from the back side of the FEOL layer than the dielectric liner.

9. The semiconductor device of claim 1, further comprising a back-end-of-line (BEOL) layer on the front side of the FEOL layer.

10. A semiconductor device, comprising:
a front-end-of-line (FEOL) layer including a FEOL device;
a back-end-of-line (BEOL) layer on a front side of the FOEL layer;
a backside power line on a back side of the FEOL layer;
a conductive structure that contacts the FEOL device at the front side of the FEOL layer and that extends through the FEOL layer to contact the backside power line, including a frontside part that includes a metal liner and a first fill material and a backside part that includes a second fill material having an outer surface that aligns with an outer surface of the metal liner;
a dielectric liner on sidewalls of the backside part of the conductive structure, including a first dielectric material; and
an interlayer dielectric around the dielectric liner, including a second dielectric material different from the first dielectric material.

11. The semiconductor device of claim 10, wherein the frontside part of the conductive structure includes a first metal and the metal liner includes a metal nitride.

12. The semiconductor device of claim 11, wherein the backside part of the conductive structure includes a second metal, different from the first metal.

13. The semiconductor device of claim 12, wherein the backside power line includes a third metal, different from the second metal.

14. The semiconductor device of claim 13, wherein the backside part of the conductive structure extends farther from the back side of the FEOL layer than the dielectric liner.

15. A method for forming a semiconductor device, comprising:
forming a front-end-of-line (FEOL) layer that includes a FEOL device;
forming a frontside conductive contact on the FEOL device, including a metal liner between the frontside conductive contact and the FEOL device; and
forming a backside conductive contact in electrical contact with the frontside conductive contact, an outer surface of the backside conductive contact aligning with an outer surface of the metal liner.

16. The method of claim 15, further comprising forming a dielectric-lined via through the FEOL layer.

17. The method of claim 16, further comprising forming a sacrificial plug in the dielectric-lined via before forming the frontside conductive contact.

18. The method of claim 17, further comprising etching away the sacrificial plug after forming the frontside conductive contact and before forming the backside conductive contact.

19. The method of claim 18, further comprising etching away an exposed portion of the metal liner of the frontside conductive contact after etching away the sacrificial plug and before forming the backside contact.

20. The method of claim 19, wherein forming the backside conductive contact includes selectively depositing conductive material on the frontside conductive contact after etching away the exposed portion of the metal liner.
